(19) United States
(12) Patent Application Publication
(10) Pub. No.: US 2024/0213553 A1
(43) Pub. Date: Jun. 27, 2024

(54) Battery Management System and Operation Method Thereof

(71) Applicant: LG Energy Solution, Ltd., Seoul (KR)

(72) Inventors: Sun Jong Lee, Daejeon (KR); Cheol Taek Kim, Daejeon (KR)

(21) Appl. No.: 18/539,844

(22) Filed: Dec. 14, 2023

(30) Foreign Application Priority Data
Dec. 22, 2022 (KR) 10-2022-0182381
Apr. 11, 2023 (KR) 10-2023-0047829
Dec. 1, 2023 (KR) 10-2023-0172718

(51) Int. Cl. H01M 10/42; H01M 10/48

(52) U.S. Cl. CPC H01M 10/425; H01M 10/482; H01M 2010/4271

(57) ABSTRACT

A battery management system includes: a voltmeter that measures a voltage of each of a plurality of battery banks; and a controller. The controller selects a first value based on the first value, which is a voltage variation amount of each of the plurality of battery banks during a predetermined time interval, and a second value, which is a standard deviation of a voltage variation amount of each of the plurality of battery banks per unit time; ranks the plurality of battery banks based on a first reference value, which is a ratio of the selected first value to an average value of the selected first value; and diagnoses an abnormality of at least one battery bank among the plurality of battery banks at a designated time point based on the ranked plurality of battery banks.

### CROSS-REFERENCE TO RELATED APPLICATION

This application claims the benefit under 35 U.S.C. § 119(a) of a Korean patent application filed on Dec. 22, 2022 in the Korean Intellectual Property Office and assigned Serial number 10-2022-0182381, a Korean patent application filed on Apr. 11, 2023 in the Korean Intellectual Property Office and assigned Serial number 10-2023-0047829, and a Korean patent application filed on Nov. 24, 2023 in the Korean Intellectual Property Office and assigned Serial number 10-2023-0172718, the entire disclosure of which is hereby incorporated by reference.

### TECHNICAL FIELD

The present disclosure relates to a battery management system, an operation method thereof, and a storage medium.

### BACKGROUND

Electric vehicles draw their vitality from external power sources to replenish their batteries, infusing them with the energy required for driving power. Over time, as these batteries undergo the cycles of charge and discharge throughout their stages of manufacturing and use, internal deformation and degeneration will take place. Consequently, this process can alter their physical and chemical properties, potentially resulting in defects. For instance, reduction of lithium ions from the battery's anode may not properly occur at the cathode, leading to the formation of lithium deposits, also known as dendrites, on the surface of the cathode.

As the accumulation of these lithium deposits continues, the risk of internal short between the cathode and the anode of the battery increases. Such an internal short can result in adverse effects, including undervoltage faults where the voltage drops below a certain threshold, or even the potential for ignition.

### SUMMARY

An object of embodiments of the present disclosure is to provide a battery management system and an operation method thereof, which can accurately diagnose an abnormal battery bank using voltage behaviors of battery banks during a relaxation time.

According to an embodiment of the present disclosure, a battery management system includes: a voltmeter that measures a voltage of each of a plurality of battery banks; and a controller. The controller communicates with the voltmeter, selects a first value of each of the plurality of battery banks based on the first value, which is a voltage variation amount of each of the plurality of battery banks during a predetermined time interval, and a second value, which is a standard deviation of a voltage variation amount of each of the plurality of battery banks per unit time; ranks the plurality of battery banks based on a first reference value, which is a ratio of the selected first value of each of the plurality of battery banks to an average value of the selected first value of each of the plurality of battery banks; and diagnoses an abnormality of at least one battery bank among the plurality of battery banks at a designated time point based on the ranked plurality of battery banks.

According to an embodiment, when the first value of at least one battery bank among the plurality of battery banks is smaller than a value obtained by multiplying the second value of the at least one battery bank by a lower threshold value, the controller resets the first value without using the first value for diagnosing the abnormality of at least one battery bank.

According to an embodiment, when the first value of the at least one battery bank among the plurality of battery banks exceeds a value obtained by multiplying the second value of the at least one battery bank by an upper threshold value, the controller selects the first value to use the first value for diagnosing the abnormality of at least one battery bank.

According to an embodiment, when the first value of the at least one battery bank among the plurality of battery banks is equal to or more than the value obtained by multiplying the second value of the at least one battery bank by the lower threshold value, and is equal to or less than the value obtained by multiplying the second value of the at least one battery bank by the upper threshold value, the controller accumulates the first value of the at least one battery bank to diagnose the abnormality of at least one battery bank.

According to an embodiment, the controller calculates, as the first reference value, a ratio of the selected first value of each of the plurality of battery banks to a maximum value between the average value of the selected first value of each of the plurality of battery banks and the value obtained by multiplying the second value of each of the plurality of battery banks by the upper threshold value.

According to an embodiment, the controller sets the ranks of the plurality of battery banks in a descending order of the first reference value, and determines a battery bank ranked first to be a first battery bank, a battery bank ranked second to be a second battery bank, and a battery bank ranked last to be a third battery bank, among the plurality of battery banks.

According to an embodiment, the controller calculates a first deviation, which is a difference between the first reference value of the first battery bank and the first reference value of the second battery bank, calculates a second deviation, which is a difference between the first reference value of the second battery bank and the first reference value of the third battery bank, and diagnoses an abnormality of the first battery bank at a designated time point based on a second reference value, which is a ratio of the first deviation to the second deviation.

According to an embodiment, when the first reference value of the first battery bank exceeds a first threshold value, and the second reference value of the first battery bank exceeds a second threshold value, the controller diagnoses the first battery bank as an abnormal battery bank.

According to another embodiment of the present disclosure, a method for operating a battery management system includes: measuring a voltage of each of a plurality of battery banks; calculating a first value, which is a voltage variation amount of each of the plurality of battery banks during a predetermined time interval; calculating a second value, which is a standard deviation of a voltage variation amount of each of the plurality of battery banks per unit time; selecting the first value of each of the plurality of battery banks based on the first and second values of each of the plurality of battery banks; ranking the plurality of battery banks based on a first reference value, which is a ratio of the selected first value of each of the plurality of battery banks to an average value of the selected first value of each of the plurality of battery banks; and diagnosing an abnormality of at least one battery bank among the plurality of battery banks at a designated time point based on the ranked plurality of battery banks.

According to an embodiment, in the selecting, when the first value of at least one battery bank among the plurality of battery banks is smaller than a value obtained by multiplying the second value of the at least one battery bank by a lower threshold value, the first value is reset without being used for diagnosing the abnormality of at least one battery bank.

According to an embodiment, in the selecting, when the first value of the at least one battery bank among the plurality of battery banks exceeds a value obtained by multiplying the second value of the at least one battery bank by an upper threshold value, the first value is selected to be used for diagnosing the abnormality of at least one battery bank.

According to an embodiment, in the selecting, when the first value of the at least one battery bank among the plurality of battery banks is equal to or more than the value obtained by multiplying the second value of the at least one battery bank by the lower threshold value, and is equal to or less than the value obtained by multiplying the second value of the at least one battery bank by the upper threshold value, the first value is accumulated to diagnose the abnormality of at least one battery bank.

According to an embodiment, wherein in the ranking, the first reference value is calculated as a ratio of the selected first value of each of the plurality of battery banks to a maximum value between the average value of the selected first value of each of the plurality of battery banks, and the value obtained by multiplying the second value of each of the plurality of battery banks by the upper threshold value.

According to an embodiment, in the ranking, the plurality of battery banks are ranked in a descending order of the first reference value, and among the plurality of battery banks, a battery bank ranked first is determined to be a first battery bank, a battery bank ranked second is determined to be a second battery bank, and a battery bank ranked last is determined to be a third battery bank.

According to an embodiment, in the diagnosing, a first deviation is calculated, which is a difference between the first reference value of the first battery bank and the first reference value of the second battery bank, a second deviation is calculated, which is a difference between the first reference value of the second battery bank and the first reference value of the third battery bank, and an abnormality of the first battery bank is diagnosed at a designated time point based on a second reference value, which is a ratio of the first deviation to the second deviation.

According to an embodiment, in the diagnosing, when the first reference value of the first battery bank exceeds a first threshold value, and the second reference value of the first battery bank exceeds a second threshold value, the first battery bank is diagnosed as an abnormal battery bank.

According to another embodiment, a controller for a battery management system includes: a memory; and a processor coupled to the memory and configured to execute an operation method of the battery management system.

According to yet another embodiment, a non-transitory computer-readable storage medium having stored therein a program that causes an information processing apparatus to execute a process including: measuring a voltage of each of a plurality of battery banks; calculating a first value, which is a voltage variation amount of each of the plurality of battery banks during a predetermined time interval; calculating a second value, which is a standard deviation of a voltage variation amount of each of the plurality of battery banks per unit time; selecting the first value of each of the plurality of battery banks based on the first and second values of each of the plurality of battery banks; ranking the plurality of battery banks based on a first reference value, which is a ratio of the selected first value of each of the plurality of battery banks to an average value of the selected first value of each of the plurality of battery banks; and diagnosing an abnormality of at least one battery bank among the plurality of battery banks at a designated time point based on the ranked plurality of battery banks.

According to an embodiment, in the diagnosing, a first deviation is calculated, which is a difference between the first reference value of the first battery bank and the first reference value of the second battery bank, a second deviation is calculated, which is a difference between the first reference value of the second battery bank and the first reference value of the third battery bank, and an abnormality of the first battery bank is diagnosed at a designated time point based on a second reference value, which is a ratio of the first deviation to the second deviation.

According to an embodiment, wherein in the diagnosing, when the first reference value of the first battery bank exceeds a first threshold value, and the second reference value of the first battery bank exceeds a second threshold value, the first battery bank is diagnosed as an abnormal battery bank.

### BRIEF DESCRIPTION OF THE DRAWINGS

FIG. 1 is a view illustrating a battery pack according to an embodiment of the present disclosure.

FIG. 2 is a block diagram illustrating a configuration of a battery management system according to an embodiment of the present disclosure.

FIG. 3 is a flowchart illustrating an operation method of a battery management system according to an embodiment of the present disclosure.

FIG. 4 is a flowchart illustrating an operation method of the battery management system according to another embodiment of the present disclosure.

FIG. 5 is a graph illustrating a voltage variation of each battery bank at predetermined time intervals during a relaxation time according to an embodiment of the present disclosure.

FIG. 6 is a graph illustrating a variation of a first value of each battery bank at predetermined time intervals according to an embodiment of the present disclosure.

FIG. 7 is a graph illustrating a variation of a second value of each battery bank at predetermined time intervals according to an embodiment of the present disclosure.

FIG. 8 is a graph illustrating a variation of a first reference value of each battery bank at predetermined time intervals according to an embodiment of the present disclosure.

FIG. 9 is a block diagram illustrating a hardware configuration of a computing system that implements an operation method of the battery management system according to an embodiment of the present disclosure.

### DETAILED DESCRIPTION

Hereinafter, non-limiting examples of embodiments of the present disclosure will be described in detail with reference to the drawings. It is noted that the same components will be denoted by the same reference numerals even though they are illustrated in different drawings. When describing the embodiments herein, detailed description of related well-known configuration or a function thereof may be omitted if determined to impede the understanding of the embodiments.

In order to describe components of the embodiments, for example, terms such as “first,” “second,” “A,” “B,” “(a),” and “(b)” may be used. These terms are intended to simply discriminate a component from another without limiting the nature, sequence, or order of the component. Further, unless otherwise defined, all terms used herein, including technical and scientific terminologies, have the same meaning as commonly understood by those skilled in the art to which the embodiments of the present disclosure pertain. Terms such as those defined in commonly used dictionaries should be interpreted as having a meaning that is consistent with their meaning in the context of the relevant art, and should not be interpreted in an ideal or excessively formal sense unless clearly defined herein.

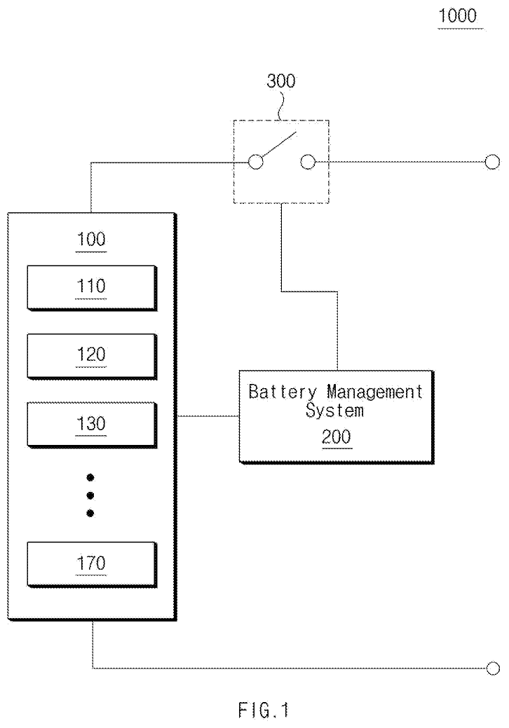

FIG. 1 is a view illustrating a battery pack 1000 according to an embodiment of the present disclosure. The battery pack 1000, for example, includes a battery module 100, a battery management system 200 (hereinafter, the “BMS 200”), and a relay 300. According to various embodiments, the battery module 100 may be battery cells. For example, the battery pack 1000 may have a cell-to-pack structure, in which battery cells are directly assembled into a pack without being divided into individual modules. This is unlike an existing battery, in which modules each consisting of battery cells are packaged.

While FIG. 1 illustrates one battery module 100, the battery pack 1000 may have a stacked structure of a plurality of battery modules. The battery module 100 may include a plurality of battery banks 110, 120, 130, 140, 150, 160, and 170 (hereinafter, the “battery banks 110 to 170”). While FIG. 1 illustrates seven battery banks, the number of battery banks is not limited thereto. The battery module 100 may include “n” battery banks (“n” is a natural number equal to or more than one).

The battery module 100 may supply power to a target apparatus (not illustrated). To this end, the battery module 100 may be electrically connected to the target apparatus. Here, the target apparatus may include an electrical, electronic, or mechanical apparatus that operates by receiving power from the battery pack 1000 including the battery module 100. For example, the target apparatus may be an electric vehicle (EV) or an energy storage system (ESS), but is not limited thereto.

Each of the battery banks 110 to 170 included in the battery module 100 may be made up of a single cell or a plurality of cells arranged either in series or in parallel. In an embodiment, the same number of cells may be connected to each other in series or in parallel in each battery bank.

According to an embodiment, the battery banks 110 to 170 may be electrically connected to each other in series or in parallel in the battery module 100, to configure a cell module assembly (CMA).

Each of the plurality of battery cells included in each of the battery banks 110 to 170 is a basic unit of a battery that can be used by charging/discharging the electrical energy, and may be, for example, but is not limited to, a lithium-ion (Li-ion) cell, a lithium-ion polymer (Li-ion polymer) cell, a nickel-cadmium (Ni—Cd) cell, or a nickel-hydride (Ni-MH) cell.

The BMS 200 may manage and/or control the state and/or operation of the battery module 100. For example, the BMS 200 may manage the charge and/or discharge of the battery banks 110 to 170 included in the battery module 100, and may manage and/or control the state and/or operation of the battery module 100.

Further, the BMS 200 may control the operation of the relay 300. For example, the BMS 200 may short-circuit the relay 300 in order to supply power to the target apparatus, and may also short-circuit the relay 300 when a charger is connected to the battery pack 1000.

The BMS 200 may monitor, for example, the voltage, current, and temperature of the battery module 100 and/or each of the battery banks 110 to 170 included in the battery module 100. For the monitoring by the BMS 200, sensors (not illustrated) or various measurement modules (not illustrated) may be additionally installed, for example, at arbitrary positions in the battery module 100 or charge/discharge pathways. The BMS 200 may calculate the parameters indicating the state of the battery module 100, such as a state of charge (SOC) or a state of health (SOH), based on measured values of the monitored voltage, current, temperature and others.

The battery banks 110 to 170 may go through changes of various internal factors over time and through repeated usages, resulting in decrease in capacity and increase in internal resistance. Based on the data of the various internal factors that change with the aging of the battery banks, the BMS 200 may diagnose an abnormality inside each of the battery banks 110 to 170.

In an embodiment, the BMS 200 uses voltage data of each of the battery banks 110 to 170 to diagnose an abnormal battery bank including, for example, a battery cell or battery bank suffering from a disconnection of an electrode tab, or a battery cell or battery bank suffering from a formation of lithium deposits in addition to the disconnection of an electrode tab. The formation of lithium deposits refers to a phenomenon wherein during the charge process of a battery cell, lithium ions from the anode are not chemically bonded to the cathode, instead remaining as metals on the surface of the cathode. In the case of a normal battery cell, lithium ions from the anode are reduced into the cathode during charge. However, in the case of a defective battery cell, some of lithium ions from the anode may be deposited as lithium metals on the surface of the cathode. When lithium byproducts grow due to the repeated formation of lithium deposits, the lithium byproducts may come into contact with the anode or the anode collector, causing an internal short between the cathode and the anode of the battery cell. The battery bank including the battery cell with the internal short self-discharges over time, and as a result, for example, the voltage may deviate from other normal battery banks.

The anode or cathode tab of a battery cell may be disconnected for various reasons such as, for example, defects in the manufacturing stage, internal deformation and degeneration through repeated charge/discharge operations, and external shock. In a case where the disconnection of an electrode tab and the formation of lithium deposits occur together in a battery cell, the electrode of the disconnected battery cell and the electrode of a normal battery cell may be connected to each other through the lithium deposits. Here, when the cathode of the disconnected battery cell has a higher SOC than the cathode of the normal battery cell, the cathodes of the two battery cells may come into contact with each other through the lithium deposits, and a charging may occur from the cathode of the disconnected battery cell to the cathode of the normal battery cell. Accordingly, a faster and more significant voltage variation may occur in the battery cell with the disconnection of an electrode tab and the formation of lithium deposits, in comparison to the normal battery cell.

The BMS 200 utilizes the phenomenon that the battery cell with the disconnection of an electrode tab and the formation of lithium deposits exhibits faster and more significant voltage variation during the relaxation time than normal battery cells. The BMS 200 may compare voltage data during the relaxation time of the battery cell with the disconnection of an electrode tab and the formation of lithium deposits, with statistical normal voltage data during the relaxation time of a normal battery cell, and identify (diagnose) the battery bank with the disconnection of an electrode tab and the formation of lithium deposits as an abnormal battery bank. The relaxation time of a battery cell or module refers to a state where the battery cell or module is not being currently charged or discharged, or is not electrically connected to a load. For example, the BMS 200 may monitor voltage values of cells or a charge/discharge current value of a battery module, to determine whether the cell or battery module is in the relaxation state.

The operation of the BMS 200 described herein below may be performed in various devices, such as a server, cloud, charger, or charger-discharger connected to the BMS 200 or a vehicle equipped with the BMS 200, through wired or wireless signals.

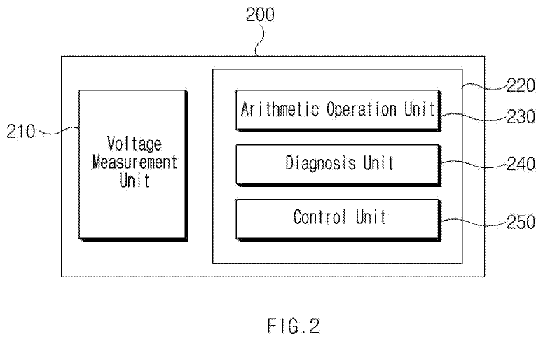

FIG. 2 is a block diagram illustrating the configuration of the BMS 200 according to an embodiment of the present disclosure.

The configuration of the BMS 200 may vary according to the environment of usage and purpose of the battery pack 1000 including the battery module 100, and may be equipped with many different operation units.

Referring to FIG. 2, the BMS 200 according to an embodiment of the present disclosure may include a voltage measurement unit 210 and a controller 220. The controller 220 may include an arithmetic operation unit 230, a diagnosis unit 240, and a control unit 250. In another embodiment, the BMS 200 may further include, for example, a current measurement unit and/or a temperature measurement unit, in addition to the voltage measurement unit 210.

The voltage measurement unit 210 is configured with a measurement device, such as a voltmeter, capable of measuring a voltage of a battery bank and/or a cell, and may measure the voltage of each of the battery banks 110 to 170 at predetermined time intervals to obtain time-series voltage data of each of the battery banks 110 to 170. In an embodiment, the voltage measurement unit 210 may calculate data of voltage rise and fall, and long-term relaxation data during charge, discharge, and relaxation time.

The arithmetic operation unit 230 performs various arithmetic operations for the diagnosis of an abnormal battery bank to be described below, by using the voltage data measured in the voltage measurement unit 210. The diagnosis unit 240 confirms, for example, whether the conditions to be described later are satisfied, by using the results of the arithmetic operations, and diagnoses an abnormal battery bank. Utilizing the result of the diagnosis, the control unit 250 may take appropriate measures for the abnormal battery bank, such as monitoring the defective battery bank and reporting to a user.

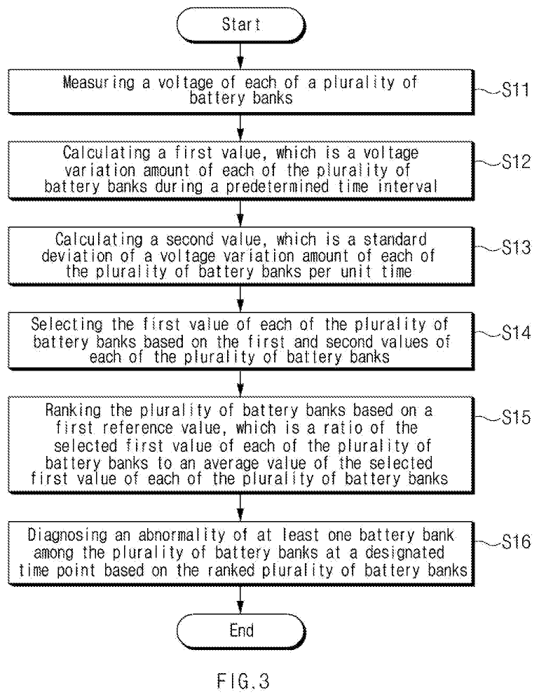

FIG. 3 is a flowchart illustrating an operation method of a battery management system according to an embodiment of the present disclosure.

Referring to FIG. 3, the operation method of the battery management system may include steps S11 to S16. According to an embodiment, the operation method of the battery management system may be performed by the BMS 200.

In step S11, the BMS 200 may measure a voltage of each of a plurality of battery banks. In step S12, the BMS 200 may calculate a first value, which is a voltage variation amount of the plurality of battery bank during a predetermined time interval. In step S13, the BMS 200 may calculate a second value, which is a standard deviation of a voltage variation amount of each of the plurality of battery banks per unit time.

In S14, the BMS 200 may select the first value of each of the plurality of battery banks based on the first and second values of each of the plurality of battery banks. In S15, the BMS 200 may rank the plurality of battery banks based on a first reference value, which is a ratio of the selected first value of each of the plurality of battery banks to an average value of the selected first value of the plurality of battery banks. In S16, the BMS 200 may diagnose an abnormality of at least one battery bank among the plurality of battery banks at a designated time point based on the ranked plurality of battery banks.

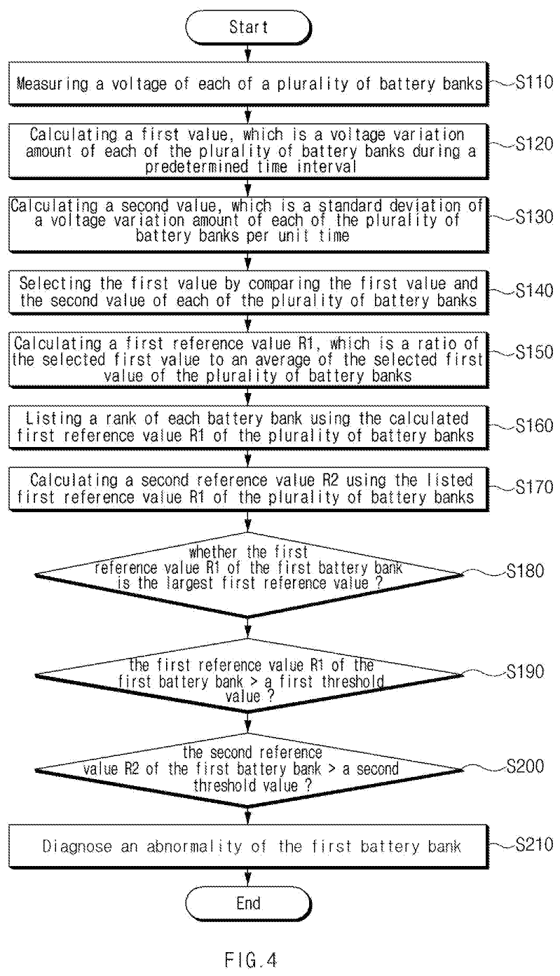

FIG. 4 is a flowchart illustrating an example operation of the BMS 200 according to another embodiment of the present disclosure.

Referring to FIG. 4, the operation method of the BMS 200 may include: measuring a first voltage of each of a plurality of battery banks at each of predetermined time intervals (S110); calculating a first value at each of the predetermined time intervals using the first voltage, wherein the first value is a voltage variation amount of the first voltage of each of the plurality of battery banks at each of the predetermined time intervals (S120); measuring a second voltage of each of the plurality of battery banks per unit time during each of the predetermined time intervals and calculating a second value at each of the predetermined time intervals using the second voltage, wherein the second value is a standard deviation of a voltage variation amount of the second voltage per unit time for each of the plurality of battery banks at each of the predetermined time intervals (S130); selecting the first value to be validated for each of the plurality of battery banks based on a comparison between the first and second values calculated at each of the predetermined time intervals (S140); calculating a first reference value R1 using a mathematical formula that represents a ratio of the selected first value to an average of the selected first value of each of the plurality of battery banks at each of the predetermined time intervals (S150); ranking the plurality of battery banks to first, second, and third battery banks at a designated time point based on the calculated first reference value R1 (S160); calculating a second reference value R2 using the calculated first reference value R1 and the ranking data (S170); determining whether the first reference value R1 of the first battery bank ranked at S160 is the largest first reference value R1 in the battery module 100 at the designated time point (S180); determining whether the first reference value R1 of the first battery bank is equal to or greater than a first threshold value at the designated time point (S190); determining whether the second reference value R2 is equal to or greater than a second threshold value at the designated time point (S200); and determining the first battery bank to be the abnormal battery bank at the designated time point (S210).

Hereinafter, the operation method of the BMS 200 and the method of diagnosing an abnormal battery bank will be described in more detail with reference to FIG. 4.

In step S110, the voltage measurement unit 210 may measure the voltage of each of the battery banks 110 to 170 at the predetermined time intervals during the relaxation time, and the controller 220 generates a graph representing the variation of the measured voltage of each of the battery banks 110 to 170.

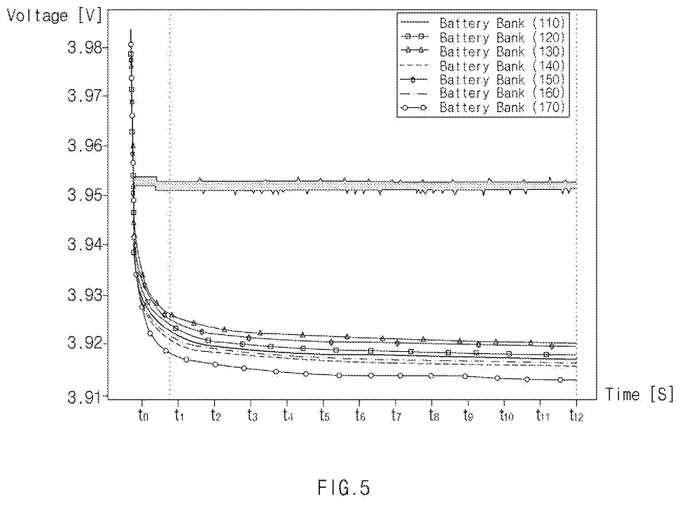

FIG. 5 is a graph illustrating the voltage measurements of the battery banks 110 to 170 at predetermined time points t1 to t12, spaced by intervals of 600 seconds from a time to when the relaxation time begins according to an embodiment of the present disclosure. That is, in the example of FIG. 5, the time to of the horizontal axis indicates the beginning of the relaxation time, and the time t12 indicates a time after a lapse of 7,200 seconds from the beginning of the relaxation time of t0. In general, the voltage of a battery bank or cell falls substantially within a relatively short time period (e.g., approximately 600 seconds) after the beginning of the relaxation time, and declines gradually thereafter. In the example of FIG. 5, the voltage of each of the battery banks 110 to 170 is around 3.98 V at the time to when the relaxation time begins, and sharply drops to around 3.92 V at the time t1 after a lapse of 600 seconds from the time t0. Referring to FIG. 5, the voltage measurement unit 210 may start measuring the voltage of each of the battery banks 110 to 170 at the time t1 which is after 600 seconds from the beginning of the relaxation time of t0. Subsequently, assuming that the predetermined interval is set to be 600 seconds, the voltage measurement unit 210 measures the voltage of each of the battery banks 110 to 170 at the time t2 which is after 600 seconds from t1. The voltage measurement unit 210 then measures the voltage of each of the battery banks 110 to 170 at the time t3 which is after 600 seconds from t2 (i.e., after 1,200 seconds from t1). Thereafter, the voltage measurement unit 210 may repeat measuring the voltage of each of the battery banks 110 to 170 at each time intervals, encompassing t4 through t12, and the controller 220 may generate a graph as illustrated in FIG. 5.

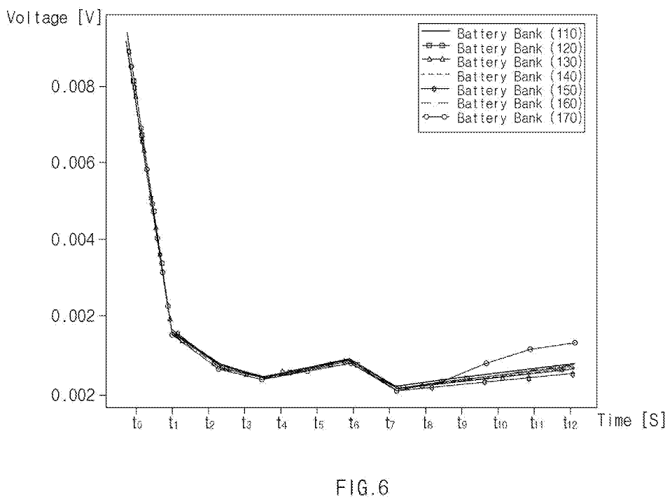

In step S120, the arithmetic operation unit 230 may calculate a first value ΔV, which is the voltage variation amount of each of the battery banks 110 to 170 at two adjacent predetermined time intervals (e.g., 600 second), by using the voltage data measured in step S110. For example, referring to FIG. 6 which is a graph representing the first value ΔV of each battery bank according to an embodiment of the present disclosure, the arithmetic operation unit 230 may calculate the first value ΔV between t1 and t2, for example, by subtracting the voltage value at the time t2 from the voltage value at the time t1. That is, in an embodiment, the arithmetic operation unit 230 may compare the voltage of each of the battery banks 110 to 170 measured at the time of t1 when 600 seconds elapse after the beginning of the relaxation time, and the voltage of each of the battery banks 110 to 170 measured at the time t2 when 1,200 seconds elapse from the beginning of the relaxation time of t0, to calculate the first value ΔV, which is the voltage variation amount of each of the battery banks 110 to 170 for 600 seconds. Subsequently, the arithmetic operation unit 230 plots the calculated first value ΔV at the time t2. The arithmetic operation unit 230 may repeat this process to calculate and plot the first value ΔV for each of the battery banks 110 to 170 at each of the times t3 to t12. In the graph of FIG. 6, the first value ΔV of the battery bank 170 is relatively high at the interval between t11 and t12, as compared to the other battery banks. From the graph, it is understood that the battery bank 170 may be an abnormal battery. In another embodiment, the predetermined time intervals may be set as 200 seconds, instead of 600 seconds, to calculate the voltage variation amount.

In step S130, the voltage measurement unit 210 and the arithmetic operation unit 230 may measure and calculate the voltage variation amount per unit time (e.g., 1 second) for each of the battery banks 110 to 170, and calculate a second value σ_{dv}, which is the standard deviation “σ” of the voltage variation amount per unit time at the predetermined time intervals. For example, separately from step S110 described above, the voltage measurement unit 210 may measure the voltage of each of the battery banks 110 to 170 every second within 600 seconds of each predetermined time interval (e.g., from each of the timings t1 to t11 until its subsequent time). Subsequently, based on the measured voltage values per unit time, the arithmetic operation unit 230 may calculate the voltage variation amount and the second value σ_{dv}, which is the standard deviation “σ” of the voltage variation amount for 1 second.

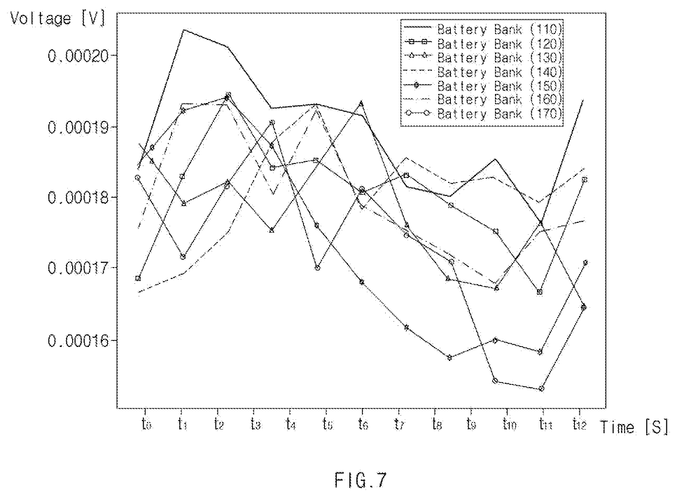

FIG. 7 is a graph representing the variation of the second value σ_{dv} calculated repeatedly at each of the predetermined time intervals of t2 to t12, for each of the battery banks 110 to 170 according to an embodiment of the present disclosure. For example, the arithmetic operation unit 230 may measure the voltage at every second within 600 seconds starting from the time t1 (e.g., when 600 seconds elapse from the beginning of the relaxation time) until the time t2 (e.g., when 1,200 seconds elapse from the beginning of the relaxation time), calculate the voltage variation amount per unit time and the standard deviation “σ” from the time t1 to t2, and plot the calculated standard deviation “σ” at the time t2. Subsequently, the arithmetic operation unit 230 may measure the voltage at every second within 600 seconds starting from the time t2 until the time t3 (e.g., when 1,800 seconds elapse from the beginning of the relaxation time), calculate the voltage variation amount per unit time and the standard deviation “σ” from the time t2 to t3, and plot the calculated standard deviation “σ” at the time t3. Then, the arithmetic operation unit 230 may measure the voltage at every second within 600 seconds starting from the time t3 until the time t4 (e.g., when 2,400 seconds elapse from the beginning of the relaxation time), calculate the voltage variation amount per unit time and the standard deviation “σ” from the time t3 to t4, and plot the calculated standard deviation “σ” at the time t4. The measuring, calculating, and plotting process may be repeated until the time t12 (e.g., when 7,200 seconds elapse from the beginning of the relaxation time), thereby generating a graph as illustrated in FIG. 7. In another embodiment, the voltage may be measured per unit time (e.g., every second) within 200 seconds of time intervals, instead of 600 seconds of time intervals, to calculate the second value σ_{dv}.

Meanwhile, since the calculation of the second value σ_{dv} may be performed separately from the calculation of the first value ΔV described above, the calculation of the second value σ_{dv} may be performed, for example, before the calculation of the first value ΔV.

In step S140, the arithmetic operation unit 230 may compare the first value ΔV and the second value σ_{dv} calculated at each of the time intervals of t2 to t12 for each of the battery banks 110 to 170, to select the first value ΔV to be validated. Here, selecting the first value ΔV refers to determining whether the calculated first value ΔV is validated to be used for diagnosing (detecting) an abnormal battery bank according to the magnitude of the second value σ_{dvj}. In an embodiment, the second value σ_{dv} of each of the battery banks 110 to 170 is associated with a noise level used to determine whether the calculated first value ΔV of each of the battery banks 110 to 170 is a valid value or noise data. For example, the arithmetic operation unit 230 may compare the first value ΔV and the second value σ_{dv} of each of the battery banks 110 to 170 at each of the time intervals of t2 to t12, and determine the first value ΔV to be noise data that cannot be used for diagnosing an abnormal battery bank when, for example, the first value ΔV is equal to or less than a value calculated using the second value σ_{dv}. In this case, the arithmetic operation unit 230 may reset or initialize the first value ΔV.

As an example, assuming that the first value ΔV and the second value σ_{dv} of the battery bank 110 are 0.2 mV and 0.3 mV, respectively, at a given time (e.g., the time t3), and the lower threshold LT is set to be 1 (one), the first value ΔV of 0.2 mV at the given time would be less than 0.3 mV obtained by multiplying the second value σ_{dv} of 0.3 mV by the lower threshold LT of 1. Accordingly, the first value ΔV of 0.2 mV at the given time is determined to be noise data, and is reset or initialized without using it for the diagnosis of an abnormal battery bank.

In the meantime, when the first value ΔV of at least one of the battery banks 110 to 170 exceeds a value obtained by multiplying the second value σ_{dv} by an upper threshold UT, the arithmetic operation unit 230 may determine the first value ΔV of the corresponding battery bank to be useful for diagnosing an abnormal battery bank, and maintain the first value ΔV as valid data. For example, assuming that the first value ΔV and the second value σ_{dv} of the battery bank 110 are 0.7 mV and 0.3 mV, respectively, at a given time (e.g., the time t3) and the upper threshold UT is set to be 2 (two), the first value ΔV of 0.7 mV at the given time would be greater than 0.6 mV obtained by multiplying the second value σ_{dv} of 0.3 mV by the upper threshold UT of 2 (two). Accordingly, the first value ΔV of 0.7 mV at the given time is determined to be valid data, and is used for diagnosing an abnormal battery bank. That is, for example, the arithmetic operation unit 230 may determine the first value ΔV of 0.7 mV for the corresponding battery bank (e.g., the battery bank 110) at the given time (e.g., the time t3) to be the first value ΔV selected according to the second value σ_{dv}. According to an embodiment, the selected first value ΔV may be indicated by “dV” to be distinguished from the first value ΔV before the selection.

Meanwhile, when the first value ΔV of at least one of the battery banks 110 to 170 is equal to or greater than the value obtained by multiplying the second value σ_{dv} by the lower threshold LT and is equal to or less than the value obtained by multiplying the second value σ_{dv} by the upper threshold UT, the arithmetic operation unit 230 may accumulate the first value ΔV of the corresponding battery bank, and the accumulated first value ΔV may be used for diagnosing an abnormal battery bank at a later time. That is, for example, when the first value ΔV of the battery bank 110 is equal to or greater than the value obtained by multiplying the second value σ_{dv} by the lower threshold LT (e.g., 0.3 mV), and is equal to or less than the value obtained by multiplying the second value σ_{dv} by the upper threshold UT (e.g., 0.6 mV), the arithmetic operation unit 230 determines that the first value ΔV of the corresponding battery bank is not noise data but also inadequate for diagnosing an abnormal battery bank. Then, the arithmetic operation unit 230 may accumulate the first value ΔV of the corresponding battery bank over multiple time periods, and use the accumulated first value ΔV to diagnose an abnormal battery bank at a later time. Accordingly, the arithmetic operation unit 230 may recalculate the first value ΔV of each of the battery banks 110 to 170, add the recalculated first value ΔV to the previously stored first value ΔV, and compare the accumulated first value ΔV with the second value σ_{dv} again for a diagnosis.

In this way, the arithmetic operation unit 230 may compare the first value ΔV and the second value σ_{dv} of each of the battery banks 110 to 170, to reset the first value ΔV determined to be noise data or accumulate the first value ΔV over multiple time periods. Therefore, an unnecessary diagnosis process based on the noise data may not be performed, which prevents an excessive diagnosis of battery banks. Although not illustrated, the selected first value ΔV obtained by comparing the first value ΔV and the second value may be represented by a graph similar to FIG. 6.

In step S150, the arithmetic operation unit 230 may calculate an average value AVG_ΔV of the selected first value ΔV of each of the battery banks 110 to 170. Further, the arithmetic operation unit 230 may calculate a maximum value Max between the average value AVG_ΔV of the selected first value ΔV of each of the battery banks 110 to 170 and the value obtained by multiplying the second value σ_{dv} of each of the battery banks 110 to 170 by the upper threshold UT (e.g., 2).

Further, the arithmetic operation unit 230 may calculate the ratio of the selected first value ΔV of each of the battery banks 110 to 170 to the maximum value Max between the average value AVG_ΔV of the selected first value ΔV of each of the battery banks 110 to 170 and the value obtained by multiplying the second value σ_{dv} of each of the battery banks 110 to 170 by the upper threshold UT (e.g., 2), as the first reference value R1 of each of the battery banks 110 to 170 at the predetermined time intervals.

In an embodiment, the arithmetic operation unit 230 may calculate the first reference value R1 of each of the battery banks 110 to 170 using Equation 1 below.

$$\begin{matrix}First Reference \\ Value ( R 1 )\end{matrix} = \frac{First Value ( Δ V )}{Max [ {AVG}_{Δ V} , Second Value ( {σ}_{dv} ) * UT ]} \qquad [ Equation 1 ]$$

As described above, the arithmetic operation unit 230 may use the Max function for the denominator of Equation 1 to calculate the first reference value R1. Specifically, the arithmetic operation unit 230 may use the Max function to input, into the denominator of Equation 1, the maximum value between the average value AVG_ΔV of the selected first value ΔV of each of the battery banks 110 to 170 and the value obtained by multiplying the second value σ_{dv} of each of the battery banks 110 to 170 by the upper threshold UT. By using the Max function for the denominator of Equation 1 as described above, the arithmetic operation unit 230 may make a setting such that the diagnosis of an abnormal battery bank is performed using the first reference value R1 only when the selected first value ΔV of a battery bank is somewhat greater than the noise level, e.g., when the selected first value ΔV is greater than the value obtained by multiplying the second value σ_{dv} by the upper threshold UT, thereby decreasing the number of unnecessary diagnosis processes.

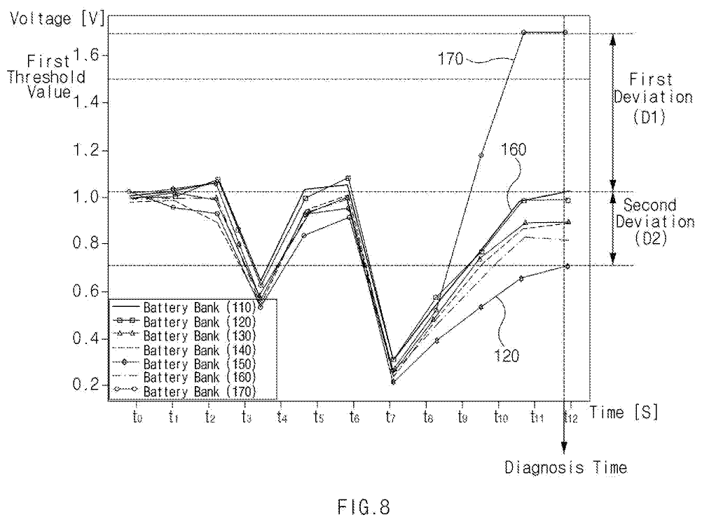

FIG. 8 is a graph illustrating the variation of the first reference value R1 of each battery bank according to an embodiment of the present disclosure.

In FIG. 8, the first reference value R1 calculated by the arithmetic operation unit 230 is plotted for each of the battery banks 110 to 170 at each of the predetermined time intervals of t2 to t12 (e.g., 600 seconds). The first reference value R1 is, for example, a value calculated by inputting the selected first value ΔV and the second value σ_{dv} of each of the battery banks 110 to 170 calculated by the arithmetic operation unit 230 at the intervals of 600 seconds (or 200 seconds), into Equation 1 as described above. Other aspects of FIG. 8 including the calculation of the second reference value R2 will be described herein below.

In step S160, the arithmetic operation unit 230 may rank the battery banks 110 to 170 either at each of the time intervals of t2 to t12 or at a designated time point (e.g., at t12), based on the calculated first reference value R1 of each of the battery banks 110 to 170. In the example of FIG. 8, assuming that the time t12 is designated as timing for the diagnosis, the arithmetic operation unit 230 may determine the battery bank 170 which has been ranked first with the largest first reference value R1 at the designated time t12 to be “a first battery bank B1,” determine the battery bank 160 ranked second with the second largest first reference value R1 at the designated time t12 to be “a second battery bank B2,” and determine the battery bank 110 ranked last with the smallest first reference value R1 at the designated time 12 to be “a third battery bank B3.”

In step S170, the arithmetic operation unit 230 calculates the second reference value R2 using the first reference value R1 represented in FIG. 8 and Equation 2 below.

$$\begin{matrix}Second Reference \\ Value ( R 2 )\end{matrix} = \frac{First Deviation ( D 1 )}{Second Deviation ( D 2 )} = \frac{( R {1}_{B 1} ) - ( R {1}_{B 2} )}{( R {1}_{B 2} ) - ( R {1}_{B 3} )} \qquad [ Equation 2 ]$$

That is, according to an embodiment, the arithmetic operation unit 230 may calculate, as the second reference value R2, a ratio of a first deviation D1 to a second deviation D2. As illustrate in FIG. 8, the first deviation D1 is a difference between a first reference value R1_{B1} of the first battery bank B1 determined to be a potential abnormal battery bank with the largest voltage variation amount based on the first reference value R1 at the time t12, and a first reference value R1_{B2} of the second battery bank B2 with the second largest voltage variation amount based on the first reference value R1 at the time t12. The second deviation D2 is a difference between a first reference value R1_{B2} of the second battery bank B2 and a first reference value R1_{B3} of the third battery bank B3 with the smallest voltage variation amount based on the first reference value R1.

When the first reference value R1 and the second reference value R2 are calculated as described above, the diagnosis unit 240 confirms whether the conditions described below are satisfied, to determine whether the first battery bank B1 with the largest first reference value R1 (e.g., the battery bank 170) is an abnormal battery bank.

In step S180, the diagnosis unit 240 first confirms whether the first battery bank B1 (e.g., the battery bank 170) determined in step S160 has the largest first reference value R1 at the designated time point (e.g., t12) in the battery module 100 (first condition). In the example of FIG. 8, the battery bank 170 determined to be the first battery bank B1 exhibits the largest first reference value R1 in the battery module 100 at the designated time point t12.

In step S190, the diagnosis unit 240 confirms whether the first reference value R1 of the first battery bank B1 (e.g., the battery bank 170) is equal to or greater than a predetermined first threshold R1_{threshold} at the designated time point of t12 (second condition). In the example of FIG. 8, the first reference value R1 of the battery bank 170 is greater than the predetermined first threshold R1_{threshold} of 1.5.

In step S200, the diagnosis unit 240 confirms whether the second reference value R2 calculated above is greater than a predetermined second threshold R2_{threshold} at the designated time point t12 (third condition). In the example of FIG. 8, at the time t12 for the designated diagnosis time, the first reference value R1 of the battery bank 170 is 1.75, the first reference value R1 of the battery bank 160 is 1.05, and the first reference value R1 of the battery bank 110 is 0.7. Accordingly, the second reference value R2 becomes 2 (two) (0.7/0.35), which is greater than the predetermined second threshold R2_{threshold} of 1.

In step S210, when it is confirmed that all of the three conditions described above are satisfied at the time t12 for the diagnosis, the diagnosis unit 240 diagnoses the battery bank 170 determined to be the first battery bank B1 as an abnormal battery bank. That is, according to an embodiment, the diagnosis unit 240 may diagnose the battery bank 170 as an abnormal battery bank including a battery cell with the disconnection of an electrode tab or both the disconnection of an electrode tab and the formation of lithium deposits.

Then, as a measure of diagnosis, the control unit 250 may track and monitor whether the internal short occurs in the battery bank 170 which has been diagnosed as an abnormal battery bank, and further, may provide information on the battery bank 170 to the user. In an embodiment, the control unit 250 may provide, to a user terminal, the information on the battery bank 170 with the disconnection of an electrode tab or both the disconnection of an electrode tab and the formation of lithium deposits through a communication unit (not illustrated). Further, the control unit 250 may provide the information of the battery bank 170 using a display (not illustrated) mounted in, for example, a vehicle or a charger.

When any of the conditions described in S180, S190, and S200 is not met at the designated time point t12, the process may return to S110 to continue the measuring and calculating. In another embodiment, the process may not return to S110 but return to any of the prior processes to continue the diagnosis.

As described above, according to the battery management system 200 of the embodiment described herein, it is possible to diagnose an abnormal battery bank including a battery cell with the disconnection of an electrode tab or both the disconnection of an electrode tab and the formation of lithium deposits, by using voltage behaviors of battery banks during the relaxation time.

Conventionally, the phenomenon of lithium deposits has been diagnosed using voltage data of a battery, in which lithium deposits are significantly formed, during the relaxation time after charge. However, the conventional method has a difficulty in determining the abnormality of voltage due to the marginal effect of the formed lithium deposits on the measured voltage of the battery.

In contrast, the battery management system 200 of the present disclosure may accurately diagnose an abnormal battery bank based on voltage variation amounts of a plurality of battery banks during a relaxation time, for example, by comparing the voltage variation amounts of the respective battery banks and ranking the battery banks according to the voltage variation amounts so as to analyze both of the short-term and long-term voltage behavior features of the battery banks.

The battery management system 200 of the present disclosure may diagnose a battery bank with the disconnection of an electrode tab and the formation of lithium deposits at an early stage by using the voltage variation amounts of battery banks, which ensures the safety and reliability of battery energy. Further, the battery management system 200 of the present disclosure may diagnose a battery bank with the disconnection of an electrode tab and the formation of lithium deposits even in a state where the battery is installed in a vehicle, so that an abnormal battery bank may be easily and quickly diagnosed without needing to be separated from the vehicle.

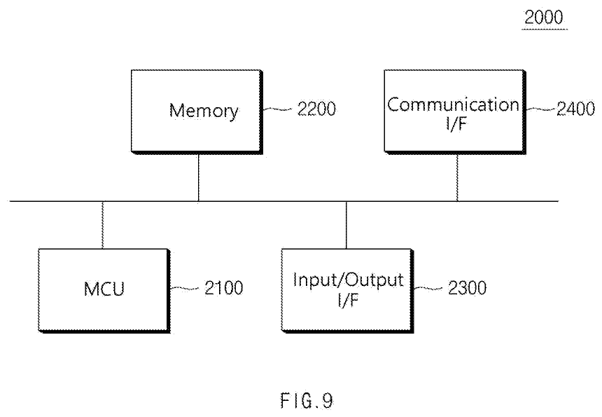

FIG. 9 is a block diagram illustrating a hardware configuration of a computing system that implements the operation method of the battery management system according to an embodiment of the present disclosure.

Referring to FIG. 9, a computing system 2000 according to an embodiment may include an MCU 2100, a memory 2200, an input/output I/F 2300, and a communication I/F 2400.

The MCU 2100 may be a processor that executes various programs stored in the memory 2200, processes various data used for the programs, and executes the functions of the BMS 200 illustrated in FIG. 1. The MCU 2100, for example, may comprise general purpose computers, which are programmed in software to carry out the functions described herein. The software may be downloaded to the computer in electronic form, over a network, for example, or it may, alternatively, or additionally, be provided and/or stored on non-transitory tangible media, such as magnetic, optical, or electronic memory.

The memory 2200 may store various programs for implementing the operation of the BMS 200 and operation data of the BMS 200 for the diagnosis of the battery banks. As needed, a plurality of memories 2200 may be provided. Further, the memory 2200 may be a volatile memory or a nonvolatile memory. As for the volatile memory, the memory 2200 may be, for example, a RAM, a DRAM, or an SRAM. As for the nonvolatile memory, the memory 2200 may be, for example, a ROM, a PROM, an EAROM, an EPROM, an EEPROM, or a flash memory. The examples of the memory 2200 may not be limited to those described above.

The input/output I/F 2300 may connect the MCU 2100 with an input device (not illustrated) such as a keyboard, a mouse, or a touch panel, and an output device (not illustrated) such as a display, in order to transmit and receive data.

The communication I/F 2400 is configured to transmit and receive various data to/from a server, and may be any of various devices capable of supporting a wired or wireless communication. For example, through the communication I/F 2400, various programs or data for the voltage measurement and the abnormality diagnosis may be transmitted and received to/from a separate external server via either a wired communication or a wireless communication.

From the foregoing, it will be appreciated that various embodiments of the present disclosure have been described herein for purposes of illustration, and that various modifications may be made without departing from the scope and spirit of the present disclosure.

Accordingly, the embodiments disclosed herein merely illustrate the technical idea of the present disclosure without limiting the scope thereof. The protection scope of the present disclosure should be interpreted based on the scope indicated in the following claims, and other technical concepts equivalent to the scope of the claims should be construed as being included in the protection scope of the present disclosure.

What is claimed is:

1. A battery management system comprising:
a voltmeter configured to measure a voltage of each of a plurality of battery banks; and
a controller in communication with the voltmeter and configured to:
select a first value of each of the plurality of battery banks based on the first value, which is a voltage variation amount of each of the plurality of battery banks during a predetermined time interval, and a second value, which is a standard deviation of a voltage variation amount of each of the plurality of battery banks per unit time;
rank the plurality of battery banks based on a first reference value, which is a ratio of the selected first value of each of the plurality of battery banks to an average value of the selected first value of each of the plurality of battery banks; and
diagnose an abnormality of at least one battery bank among the plurality of battery banks at a designated time point based on the ranked plurality of battery banks.

2. The battery management system according to claim 1, wherein when the first value of at least one battery bank among the plurality of battery banks is smaller than a value obtained by multiplying the second value of the at least one battery bank by a lower threshold value, the controller resets the first value without using the first value for diagnosing the abnormality of at least one battery bank.

3. The battery management system according to claim 2, wherein when the first value of the at least one battery bank among the plurality of battery banks exceeds a value obtained by multiplying the second value of the at least one battery bank by an upper threshold value, the controller selects the first value to use the first value for diagnosing the abnormality of at least one battery bank.

4. The battery management system according to claim 3, wherein when the first value of the at least one battery bank among the plurality of battery banks is equal to or more than the value obtained by multiplying the second value of the at least one battery bank by the lower threshold value, and is equal to or less than the value obtained by multiplying the second value of the at least one battery bank by the upper threshold value, the controller accumulates the first value of the at least one battery bank to diagnose the abnormality of at least one battery bank.

5. The battery management system according to claim 4, wherein the controller calculates, as the first reference value, a ratio of the selected first value of each of the plurality of battery banks to a maximum value between the average value of the selected first value of each of the plurality of battery banks and the value obtained by multiplying the second value of each of the plurality of battery banks by the upper threshold value.

6. The battery management system according to claim 5, wherein the controller ranks the plurality of battery banks in a descending order of the first reference value, and determines a battery bank ranked first to be a first battery bank, a battery bank ranked second to be a second battery bank, and a battery bank ranked last to be a third battery bank, among the plurality of battery banks.

7. The battery management system according to claim 6, wherein the controller calculates a first deviation, which is a difference between the first reference value of the first battery bank and the first reference value of the second battery bank, calculates a second deviation, which is a difference between the first reference value of the second battery bank and the first reference value of the third battery bank, and diagnoses an abnormality of the first battery bank at a designated time point based on a second reference value, which is a ratio of the first deviation to the second deviation.

8. The battery management system according to claim 7, wherein when the first reference value of the first battery bank exceeds a first threshold value, and the second reference value of the first battery bank exceeds a second threshold value, the controller diagnoses the first battery bank as an abnormal battery bank.

9. A method for operating a battery management system, the method comprising:
measuring a voltage of each of a plurality of battery banks;
calculating a first value, which is a voltage variation amount of each of the plurality of battery banks during a predetermined time interval;
calculating a second value, which is a standard deviation of a voltage variation amount of each of the plurality of battery banks per unit time;
selecting the first value of each of the plurality of battery banks based on the first and second values of each of the plurality of battery banks;
ranking the plurality of battery banks based on a first reference value, which is a ratio of the selected first value of each of the plurality of battery banks to an average value of the selected first value of each of the plurality of battery banks; and
diagnosing an abnormality of at least one battery bank among the plurality of battery banks at a designated time point based on the ranked plurality of battery banks.

10. The method for operating the battery management system according to claim 9, wherein in the selecting,
when the first value of at least one battery bank among the plurality of battery banks is smaller than a value obtained by multiplying the second value of the at least one battery bank by a lower threshold value, the first value is reset without being used for diagnosing the abnormality of at least one battery bank.

11. The method for operating the battery management system according to claim 10, wherein in the selecting,
when the first value of the at least one battery bank among the plurality of battery banks exceeds a value obtained by multiplying the second value of the at least one battery bank by an upper threshold value, the first value is selected to be used for diagnosing the abnormality of at least one battery bank.

12. The method for operating the battery management system according to claim 11, wherein in the selecting,
when the first value of the at least one battery bank among the plurality of battery banks is equal to or more than the value obtained by multiplying the second value of the at least one battery bank by the lower threshold value, and is equal to or less than the value obtained by multiplying the second value of the at least one battery bank by the upper threshold value, the first value is accumulated to diagnose the abnormality of at least one battery bank.

13. The method for operating the battery management system according to claim 12, wherein in the ranking,
the first reference value is calculated as a ratio of the selected first value of each of the plurality of battery banks to a maximum value between the average value of the selected first value of each of the plurality of battery banks, and the value obtained by multiplying the second value of each of the plurality of battery banks by the upper threshold value.

14. The method for operating the battery management system according to claim 13, wherein in the ranking,
the plurality of battery banks are ranked in a descending order of the first reference value, and
among the plurality of battery banks, a battery bank ranked first is determined to be a first battery bank, a battery bank ranked second is determined to be a second battery bank, and a battery bank ranked last is determined to be a third battery bank.

15. The method for operating the battery management system according to claim 14, wherein in the diagnosing,
a first deviation is calculated, which is a difference between the first reference value of the first battery bank and the first reference value of the second battery bank,
a second deviation is calculated, which is a difference between the first reference value of the second battery bank and the first reference value of the third battery bank, and
an abnormality of the first battery bank is diagnosed at a designated time point based on a second reference value, which is a ratio of the first deviation to the second deviation.

16. The method for operating the battery management system according to claim 15, wherein in the diagnosing,
when the first reference value of the first battery bank exceeds a first threshold value, and the second reference value of the first battery bank exceeds a second threshold value, the first battery bank is diagnosed as an abnormal battery bank.

17. A controller for a battery management system, the controller comprising:
a memory; and
a processor coupled to the memory and configured to execute the method according to claim 9.

18. A non-transitory computer-readable storage medium having stored therein a program that causes an information processing apparatus to execute a process including:
measuring a voltage of each of a plurality of battery banks;
calculating a first value, which is a voltage variation amount of each of the plurality of battery banks during a predetermined time interval;
calculating a second value, which is a standard deviation of a voltage variation amount of each of the plurality of battery banks per unit time;
selecting the first value of each of the plurality of battery banks based on the first and second values of each of the plurality of battery banks;
ranking the plurality of battery banks based on a first reference value, which is a ratio of the selected first value of each of the plurality of battery banks to an average value of the selected first value of each of the plurality of battery banks; and
diagnosing an abnormality of at least one battery bank among the plurality of battery banks at a designated time point based on the ranked plurality of battery banks.

19. The non-transitory computer-readable storage medium according to claim 18, wherein in the diagnosing,
a first deviation is calculated, which is a difference between the first reference value of the first battery bank and the first reference value of the second battery bank,
a second deviation is calculated, which is a difference between the first reference value of the second battery bank and the first reference value of the third battery bank, and
an abnormality of the first battery bank is diagnosed at a designated time point based on a second reference value, which is a ratio of the first deviation to the second deviation.

20. The non-transitory computer-readable storage medium according to claim 19, wherein in the diagnosing,
when the first reference value of the first battery bank exceeds a first threshold value, and the second reference value of the first battery bank exceeds a second threshold value, the first battery bank is diagnosed as an abnormal battery bank.
